(19) United States
(12) Patent Application Publication
(10) Pub. No.: US 2013/0092238 A1
(43) Pub. Date: Apr. 18, 2013

(54) ORGANIC THIN-FILM SOLAR CELL AND PRODUCTION METHOD FOR THE SAME

(71) Applicant: Asahi Glass Company, Limited, Tokyo (JP)

(72) Inventors: Yuichiro OGATA, Tokyo (JP); Shinya Tahara, Tokyo (JP); Yuriko Kaida, Tokyo (JP)

(73) Assignee: ASAHI GLASS COMPANY, LIMITED, Tokyo (JP)

(21) Appl. No.: 13/706,850

(22) Filed: Dec. 6, 2012

Related U.S. Application Data
(63) Continuation of application No. PCT/JP2011/064973, filed on Jun. 29, 2011.

(30) Foreign Application Priority Data
Jun. 30, 2010 (JP) 2010-150500

(51) Int. Cl. H01L 31/0352; H01L 51/00; H01L 31/0256

(52) U.S. Cl. CPC H01L 31/035281; H01L 31/0256; H01L 51/0001
USPC 136/263; 136/252; 438/82

(57) ABSTRACT

There are provided an organic thin-film solar cell having high charge transport efficiency and increased photoelectric conversion efficiency, and a method for producing the organic thin-film solar cell. An organic thin-film solar cell including in series a transparent substrate 2, a cathode 3, a photoelectric conversion layer 7 having a regular phase-separated structure composed of an electron donor layer 5, and an electron acceptor layer 6, at least one of the electron acceptor layer 6 and the electron donor layer 5 having a liquid crystalline organic material containing oriented liquid crystalline molecules, an anode 9, and a substrate 10.

### CROSS-REFERENCE TO RELATED APPLICATIONS

This application is a continuation of prior International Application No. PCT/JP2011/064973 filed on Jun. 29, 2011, which is based upon and claims the benefit of priority from Japanese Patent Application No. 2010-150500 filed on Jun. 30, 2010; the entire contents of all of which are incorporated herein by reference.

### FIELD

Embodiments of the present invention relates to an organic thin-film solar cell and a producing method for the same and, in particular, to an organic thin-film solar cell having high charge transport efficiency in a photoelectric conversion layer and excellent photoelectric conversion efficiency.

### BACKGROUND

In recent years, a solar cell gets attention as a photoelectric conversion element using light energy in a growing demand for alternative energy. As the solar cell, a silicon substrate solar cell using silicon as raw material is mainly put to practical use, but the silicon substrate solar cell is high in material cost and requires a high-temperature treatment process and is thus likely to be high in process cost.

For this reason, the practical use of a solar cell using an organic material (hereinafter, referred to as an “organic solar cell”) is under consideration recently. The organic solar cell does not require the high-temperature treatment process and can be produced as a sheet-like substrate, and therefore can be reduced in cost. In addition, the organic solar cell has less constraint in material and is therefore desired to be put into practical use.

As the organic solar cell, an organic dye-sensitized solar cell or organic thin-film solar cells of a Schottky type, a pn junction type, and a bulk heterojunction type are suggested. Generally, in the organic thin-film solar cell, electric power is generated such that, for example as illustrated in FIG. 5, (1) an exciton R is generated by light absorption, (2) then the exciton R is dissociated into a pair of carriers (hole and electron) at a joint surface (interface) S between an electron donor layer and an electron acceptor layer, and (3) the dissociated pair of carriers (hole h and electron e) are separated and reach respective electrodes 3, 9.

As the bulk heterojunction type organic thin-film solar cell among the aforementioned organic thin-film solar cells, a bulk heterojunction type organic thin-film solar cell in which a layer made by uniformly mixing the electron donor substance and the electron acceptor substance is formed between a transparent electrode and a counter electrode facing it is known (JP-A 2006-032636). Such a structure is believed to ensure a wide joint surface between the electron donor layer and the electron acceptor layer, so that the exciton generated by light absorption easily reaches a dissociation place to efficiently promote the process of dissociation into a pair of carriers.

However, the distance of the exciton capable of moving without deactivation (exciton diffusion distance) is generally about 10 nm, and the distance from the generation place to the dissociation place of the exciton needs to fall within the abovementioned exciton diffusion distance for the exciton generated in the process (1) to be dissociated in the process (2) and utilized as photovoltaic power. In the bulk heterojunction structure, the size and morphology of each electron donor layer 5 and each electron acceptor layer 6 are not uniform, for example, as illustrated in FIG. 6, and the distance from the generation place of the exciton R to the joint surface (interface) S between the electron donor layer 5 and the electron acceptor layer 6 does not always fall within the aforementioned exciton diffusion distance. In this case, the exciton R generated in the electron donor layer 5 cannot reach the interface S and disappears without being dissociated into a pair of carriers, bringing about a problem of failing to sufficiently improve the charge separation efficiency.

Further, the material used for an electron donor (p-type semiconductor) of the bulk heterojunction type is generally low in light absorption coefficient and insufficient in absorption amount of sunlight and is therefore tried to be improved in light absorption amount by thickening the photoelectric conversion layer. However, in the photoelectric conversion layer with a thick film thickness, it is difficult to ensure a fixed charge transport path in the layer and possibly fail to sufficiently improve the charge transport efficiency.

Furthermore, since the bulk heterojunction structure is determined by the process conditions at the time of production such as the composition ratio of a mixture, thermal treatment condition and so on, a phase-separated structure is difficult to control and is poor in reproducibility, leading to a problem of hardly improving the charge separation efficiency and the charge transport efficiency. In general, when the area of the whole solar cell is increased, the internal states of the electron donor layer and the electron acceptor layer in the photoelectric conversion layer become difficult to control, bringing about a problem of failing to sufficiently increase the charge mobility and thus failing to achieve the stable photoelectric conversion efficiency.

### SUMMARY OF THE INVENTION

Embodiments of the present invention has been made to solve the above problems and its object is to provide an organic thin-film solar cell having excellent charge separation efficiency and charge transport efficiency and increased photoelectric conversion efficiency, and a method for producing the thin-film solar cell.

An organic thin-film solar cell of the embodiment is an organic thin-film solar cell including in series a transparent substrate, a cathode, a photoelectric conversion layer having a regular phase-separated structure composed of an electron donor layer and an electron acceptor layer, at least one of the electron acceptor layer and the electron donor layer having a liquid crystalline organic material containing oriented liquid crystalline molecules, an anode and a substrate.

It is preferable that each of the electron acceptor layer and the electron donor layer has cross-section of a comb-teeth shape with a plurality of teeth facing the cathode or the anode, and the teeth fit with each other to form the phase-separated structure. It is also preferable that at least one of the electron acceptor layer and the electron donor layer is formed by using a nano-imprint method. It is also preferable that the electron acceptor layer and the electron donor layer are separately and alternately formed between the cathode and the anode in a direction perpendicular thereto.

It is preferable that each of the teeth has width from 5 to 1000 nm.

It is also preferable that the electron donor layer has a thickness from a surface thereof closest to a main surface of the cathode to a surface thereof closest to a main surface of the anode ranging from 50 to 1000 nm and the electron acceptor layer has a thickness from a surface thereof closest to the main surface of the anode to a surface thereof closest to the main surface of the cathode ranging from 50 to 1000 nm.
It is also preferable that a hole transport layer is provided between the cathode and the electron donor layer, and an electron transport layer is provided between the anode and the electron acceptor layer. It is also preferable that an electron donor substance constituting the electron donor layer contains one or more kinds of liquid crystalline organic materials selected from a group consisting of a compound with only a 6-membered ring as an aromatic ring, a compound with only a 5-membered ring as an aromatic ring, and a compound with a combination of a 5-membered ring and a 6-membered ring as aromatic rings.

Further, a method for producing an organic thin-film solar cell of the embodiment, includes: a step (a) of forming a cathode electrode on a transparent substrate; a step (b) of forming a hole transport layer by forming a film of a hole transport substance on top of the cathode electrode; a step (c) of forming an electron donor layer by forming a film of an electron donor substance on top of the hole transport layer; a step (d) of forming a pattern on top of the electron donor layer by a nano-imprint method; a step (e) of forming an electron acceptor layer by forming a film of an electron acceptor substance on top of the electron donor layer having the pattern formed thereon to thereby form a photoelectric conversion layer; a step (f) of forming an electron transport layer by forming a film of an electron transport substance on top of the photoelectric conversion layer; a step (g) of forming an anode electrode on top of the electron transport layer; and a step (h) of forming a substrate on top of the anode electrode, at least one of the electron donor substance and the electron acceptor substance being a liquid crystalline organic material containing liquid crystalline molecules.

Further, it is preferable that in the method for producing an organic thin-film solar cell of the present embodiment, thermal treatment is performed between the step (d) and the step (e) or between the step (e) and the step (f) at a temperature at which the liquid crystalline material exhibits liquid crystallinity to form an orientation state of the liquid crystalline molecules.

### BRIEF DESCRIPTION OF THE DRAWINGS

FIG. 1 is a perspective view illustrating an example of an organic thin-film solar cell of the embodiment.

FIG. 2 is a sectional view illustrating a partially enlarged photoelectric conversion layer illustrated in FIG. 1.

FIG. 3A to 3G are perspective views illustrating an example of production process of the organic thin-film solar cell of the embodiment.

FIG. 4A to 4D are perspective views illustrating an example of production process of the organic thin-film solar cell of the embodiment.

FIG. 5 is a view for explaining a general photoelectric conversion process in the organic thin-film solar cell.

FIG. 6 is a sectional view illustrating an enlarged photoelectric conversion layer (bulk heterojunction structure) in an organic thin-film solar cell according to prior embodiment.

FIG. 7 is a perspective view illustrating an example of a mold used in the production process of the organic thin-film solar cell of the embodiment.

### DETAILED DESCRIPTION

Hereinafter, the embodiment of the present invention will be described in detail. An organic thin-film solar cell according to an embodiment is an organic thin-film solar cell including a transparent substrate, a cathode, a photoelectric conversion layer having a regular phase-separated structure composed of an electron donor layer and an electron acceptor layer, at least one of the electron acceptor layer and the electron donor layer having a liquid crystalline organic material containing oriented liquid crystalline molecules, an anode and a substrate.

According the organic thin-film solar cell of the embodiment, both the charge separation efficiency and the charge transport efficiency can be improved and the charge generation amount is therefore increased to stably achieve excellent photoelectric conversion efficiency by making a photoelectric conversion layer in a regular phase-separated structure composed of an electron donor layer and an electron acceptor layer and making at least one of an electron donor substance constituting the electron donor layer and an electron acceptor substance constituting the electron acceptor layer of a liquid crystalline organic material containing liquid crystalline molecules.

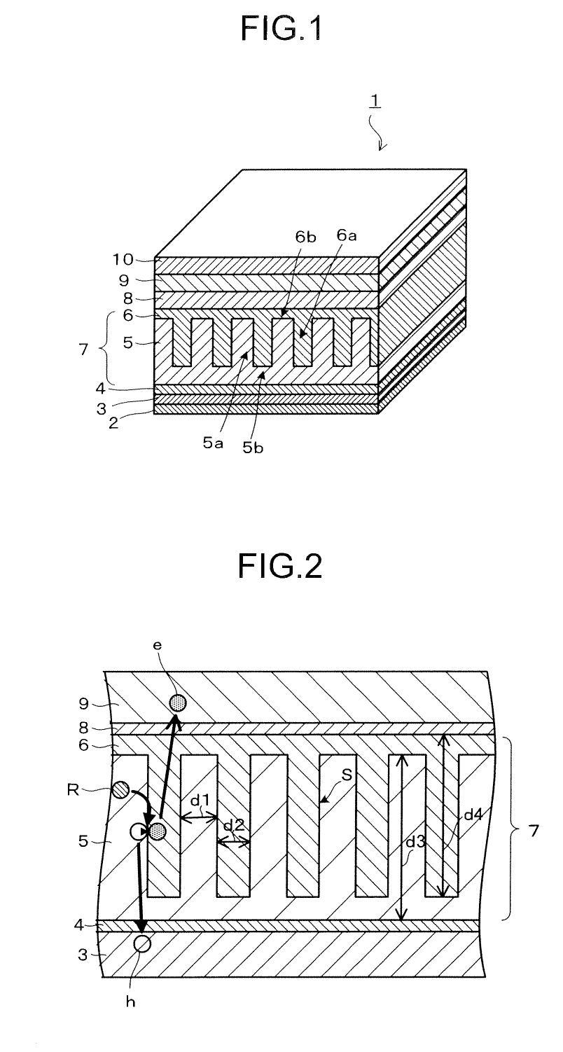

FIG. 1 is a perspective view illustrating an example of the organic thin-film solar cell of the embodiment. As illustrated in FIG. 1, an organic thin-film solar cell 1 is composed of a transparent electrode (cathode) 3, a hole transport layer 4, a photoelectric conversion layer 7 composed of an electron donor layer 5 and an electron acceptor layer 6, an electron transport layer 8, a metal electrode (anode) 9, and a substrate 10 which are stacked in order on a planar transparent substrate 2.

As illustrated in FIG. 1, the photoelectric conversion layer 7 has a regular phase-separated structure composed of the electron donor layer 5 and the electro acceptor layer 6. The electron donor layer 5 and the electron acceptor layer 6 has cross-section of a comb-teeth shape with a plurality of teeth 5a, 6a respectively such that the teeth 5a and the teeth 6a face each other in a region between the transparent electrode (cathode) 3 and the metal electrode (anode) 9. The teeth 5a of the electron donor layer 5 fit with recessed portions 6b of the electron acceptor layer 6 and the teeth 6a of the electron acceptor layer 6 fit with recessed portions 5b of the electron donor layer 5, thereby constituting the photoelectric conversion layer 7 having the regular phase-separated structure in which the teeth 5a of the electron donor layer 5 and the teeth 6a of the electron acceptor layer 6 stand upright between the facing transparent electrode (cathode) 3 and metal electrode (anode) 9 in a direction perpendicular thereto and the teeth 5a of the electron donor layer 5 and the teeth 6a of the electron acceptor layer 6 are alternately separated.

Such a structure in which the electron donor layer 5 and the electron acceptor layer 6 are alternately phase-separated in the photoelectric conversion layer 7 can increase the area of a joint surface S between the electron donor layer 5 and the electron acceptor layer 6. This increases the area where an exciton R generated in the electron donor layer 5 can be dissociated into a pair of carriers (a hole h and an electron e) as illustrated in FIG. 2 to improve the charge separation efficiency.

Further, the structure in which the electron donor layer 5 and the electron acceptor layer 6 are phase-separated regularly and at small pitches as described above reduces the percentage of the exciton R disappearing without being separated into a pair of carriers before reaching the joint surface (interface) S and therefore can improve the charge separation efficiency. The regular phase-separated structure can be obtained by forming a pattern on the surface of one of the electron donor layer 5 and the electron acceptor layer 6, for example, by a later-described nano-imprint method. This enables formation of the phase-separated structure by controlling a pitch d1 of the electron donor layer 5 and a pitch d2 of the electron acceptor layer 6 so that the distance from the place where the exciton R is generated to the joint surface S between the electron donor layer 5 and the electron acceptor layer 6 becomes an appropriate distance with respect to an exciton diffusion distance. Thus, an excellent charge separation efficiency can be achieved with good reproducibility.

Examples of an electron donor substance constituting the electron donor layer 5 include compounds containing an aromatic ring. Among them, a compound with only a 6-membered ring as an aromatic ring, a compound with only a 5-membered ring as an aromatic ring, and a compound with a combination of a 5-membered ring a and 6-membered ring as aromatic rings are preferable. As the compound with only a 6-membered ring as an aromatic ring, polyphenylene or phenylenevinylene polymer is preferable. Among them, Poly [2-methoxy-5-(ethylhexyloxy)-1,4-phenylenevinylene] or Poly [2-methoxy-5-(3′,7′-dimethyloctyloxy)-1, 4-phenylenevinylene] is preferable. Examples of the compound with only a 5-membered ring as an aromatic ring and the compound with a combination of a 5-membered ring and a 6-membered ring as aromatic rings include a single-ring compound, a condensed-ring compound, and a condensed-ring polymer. The condensed-ring polymer may be a homopolymer or a copolymer of the condensed-ring compound. Among them, a single-ring compound, condensed-ring compound, or condensed-ring polymer having a chalcogen atom is preferable. The single-ring compound, condensed-ring compound, and condensed-ring polymer having a chalcogen atom are those having an oxygen atom, a sulfur atom, a selenium atom, or a tellurium atom in addition to carbon atom in the aromatic ring structure. As the chalcogen atom, the sulfur atom is preferable. The number of sulfur atoms in the aromatic ring is preferably one or two. A substituent may exist in the aromatic ring, and examples thereof include an alkyl group, a fluorine containing alkyl group, and a fluorine atom. Among them, the alkyl group is preferable. Examples of the alkyl group include a linear alkyl group, a branched alkyl group, and a cyclic alkyl group, and the linear alkyl group or the branched alkyl group is preferable. The carbon number of the alkyl group may be 1 to 24. Among them, the carbon number is preferably 6 to 16. Examples of the single-ring compound having a sulfur atom include thiophene. Examples of the condensed-ring compound having a sulfur atom include benzothiadiazole, dithienobenzothiadiazole, thienothiophene, thienopyrrole, benzodithiophene, cyclopentadithiophene, dithienosilole, thiazolothiazole, and tetrathiafulvalene. Examples of the single-ring polymer having a sulfur atom include polythiophene, and a copolymer of thiophene and phenylene. Examples of the condensed-ring polymer having a sulfur atom include a copolymer of thiophene and fluorene, a copolymer of thiophene and thienothiophene, a copolymer of thiophene and thiazolothiazole, a copolymer of thiophene and thienothiophene, a copolymer of cyclopentadithiophene and thienothiophene, a copolymer of dithienosilole and benzothiadiazole, a copolymer of fluorene and dithienobenzothiadiazole, a copolymer of fluorene and benzothiadiazole, a copolymer of dibenzosilole and dithienobezothiadiazole, a copolymer of carbazole and dithienobenzothiadiazole, a copolymer of benzodithiophene and thienopyrrole, a copolymer of benzodithiophene and thienothiophene, and a copolymer of fluorene and dithiophene. Among them, the copolymer of thiophene and thienothiophene, the copolymer of fluorene and benzothiadiazole, or the copolymer of fluorene and dithiophene is preferable. Examples of the copolymer of thiophene and thienothiophene include poly(2,5-bis(3-alkylthiophene-2-yl)thieno[3,2-b]thiophene), examples of the copolymer of fluorene and benzothiadiazole include Poly[9,9-di-n-octylfluorenyl-2,7-diyl)-alt-(benzo[2,1,3]thiadiazol-4,8-diyl], and examples of the copolymer of fluorene and dithiophene include Poly[(9,9-dioctylfluorenyl-2,7-diyl)-co-bithiophene]). Further, examples of the compound having no chalcogen atom include a polyaniline derivative, a phthalocyanine derivative, and a porphyrin derivative.

As the electron acceptor substance constituting the electron acceptor layer 6, for example, perylene or a perylene derivative, or fullerene (C₆₀) or a fullerene derivative can be mainly used. Examples of a preferable electron acceptor substance include (6,6-phenyl-C₆₁-butyric acid methyl ester (PCBM), (6,6-phenyl-C₇₁-butyric acidmethyl ester (C70-PCBM) fullerene (C₆₀) (6,6)-thienyl-C₆₁-butyric acidmethyl ester (ThCBM), carbon nanotube and so on. Among them, fullerene (C₆₀), PCBM, C70-PCBM and so on are preferable.

At least one of the electron donor layer 5 and the electron acceptor layer 6 is made of a liquid crystalline organic material containing liquid crystalline molecules. In the electron donor layer 5 or the electron acceptor layer 6 made of a liquid crystalline organic material, a reduction in charge transport efficiency in the photoelectric conversion layer 7 can be suppressed by (1) the fact that the phase structure with high orderliness is realized to provide the charge mobility similar to that of crystal, and (2) the fact that the liquid crystalline molecules tend to uniformly orient and thereby suppress generation of a so-called trap site generating a trap of charge unlike crystal.

In the electron donor layer 5 or the electron acceptor layer 6 made of a liquid crystalline organic material, the liquid crystalline molecules are oriented in a certain direction. The liquid crystalline molecules oriented in a certain direction provide an internal structure with high orderliness in which charges can smoothly move, thereby improving the mobility of the charges (the hole h and the electron e) from the dissociation place of the exciton R to the respective electrodes. From the viewpoint of ensuring an efficient charge transport path in the photoelectric conversion layer 7 to further improve the charge mobility, the liquid crystalline molecule preferably has a molecule surface oriented in a direction parallel with the transparent substrate 2 and the substrate 10.

By controlling the orientation of the liquid crystalline molecules, the inside of the whole electron donor layer 5 or electron acceptor layer 6 is formed in a uniformly highly ordered state, so that a high charge mobility can be achieved in the photoelectric conversion layer 7 also in an organic thin-film solar cell with a large area. Since the orientation state of the liquid crystalline molecules is controlled mainly by temperature adjustment, such an internal structure with high orderliness can be formed in a short time.

Examples of the electron donor substance exhibiting liquid crystallinity include an electron donor substance having liquid crystallinity among the above-described electron donor substances. In particular, examples of the electron donor substance having liquid crystallinity include a polythiophene derivative having liquid crystallinity, a copolymer derivative of thiophene and thienothiophene having liquid crystallinity, a copolymer derivative of benzothiadiazole and fluorene having liquid crystallinity, a copolymer derivative of thiophene and fluorene having liquid crystallinity and so on. Examples of the copolymer derivative of thiophene and thienothiophene having liquid crystallinity include poly(2,5-bis-(3-alkylthiophene-2-yl)thieno[3,2-b]thiophene. Examples of the copolymer derivative of thiophene and fluorene having liquid crystallinity include, for example, Poly[(9,9-dioctylfluorenyl-2,7-diyl)-co-bithiophene].

Examples of the electron acceptor substance exhibiting liquid crystallinity include a penta-addition fullerene derivative, a metal containing fullerene derivative and so on.

As the energy levels of the electron donor substance and the electron acceptor substance in the photoelectric conversion layer 7, it is required that the energy level of LUMO (excited state) of the electron acceptor substance is lower than the energy level of LUMO (excited state) of the electron donor substance and higher than HOMO (ground state) of the electron donor substance, and the energy level of HOMO (ground state) of the electron acceptor substance is lower than the energy level of HOMO (ground state) of the electron donor substance. Preferable combinations of the electron donor substance and the electron acceptor substance include a combination of the copolymer derivative of thiophene and thienothiophene and C60, a combination of the copolymer derivative of benzothiadiazole and fluorene and C60, and a combination of the copolymer derivative of thiophene and fluorene and C60 and so on.

The photoelectric conversion layer 7 only need to be configured such that at least one of the electron acceptor layer 6 and the electron donor layer 5 has a liquid crystalline organic material, namely, at least one of the electron donor substance constituting the electron donor layer 5 and the electron acceptor substance constituting the electron acceptor layer 6 is made of a liquid crystalline organic material, and the electron donor layer 5 among them is preferably made of a liquid crystalline organic material.

The pitch dl of the electron donor layer 5 in the phase separation direction and the pitch d2 of the electron acceptor layer 6 in the phase separation direction are preferably independently 5 to 1000 nm. Namely, a width d1 of teeth 5a of the electron donor layer 5 and a width d2 of teeth 6a of the electron acceptor layer 6 are preferably independently 5 to 1000 nm. When the pitches d1 and d2 in the phase separation direction exceed 1000 nm, the moving distance of the exciton R from the place where the exciton R is generated to the joint surface (interface) S is likely to exceed the exciton diffusion distance. In this case, the exciton R disappears before reaching the joint surface S and may decrease the charge separation efficiency. On the other hand, when the pitches d1 and d2 of the electron donor layer 5 and the electron acceptor layer 6 in the phase separation direction are less than 5 nm, the electron e and the hole h separated on the joint surface S are likely to recombine on another joint surface S before reaching the respective electrodes and may actually decrease the charge separation efficiency. The pitches d1 and d2 of the electron donor layer 5 and the electron acceptor layer 6 in the phase separation direction are preferably independently 5 to 200 nm and more preferably 10 to 100 nm.

A thickness d3 of the electron donor layer 5 from a surface in contact with the hole transport layer 4 to a top portion of the teeth 5a, namely, a surface closest to the electron transport layer 8 is preferably 50 to 1000 nm and more preferably 100 to 500 nm. When the thickness d3 of the electron donor layer 5 from the surface in contact with the hole transport layer 4 to the surface closest to the electron transport layer 8 is less than 50 nm, sufficient light absorption effect may not be achieved. On the other hand, when the thickness d3 of the electron donor layer 5 from the surface in contact with the hole transport layer 4 to the surface closest to the electron transport layer 8 exceeds 1000 nm, the charge transport efficiency may be decreased.

A thickness d4 of the electron acceptor layer 6 from a surface in contact with the electron transport layer 8 to a top portion of the teeth 6a, namely, a surface closest to the hole transport layer 4 is preferably 50 to 1000 nm and more preferably 100 to 500 nm. When the thickness d4 of the electron acceptor layer 6 from the surface in contact with the electron transport layer 8 to the surface closest to the hole transport layer 4 is less than 50 nm, charge balance may be disturbed. On the other hand, when the thickness d4 of the electron acceptor layer 6 from the surface in contact with the electron transport layer 8 to the surface closest to the hole transport layer 4 exceeds 1000 nm, the charge transport efficiency may be decreased.

As the transparent substrate 2, a glass substrate conventionally used in this kind of usage or a flexible polymer substrate can be used. The flexible polymer substrate is preferably excellent in chemical stability, mechanical strength and transparency, and examples thereof include, for example, polyethylene terephthalate (PET), polyethylene naphthalate (PEN), polyimide, polyetheretherketone (PEEK), polyethersulfone (PES), and polyetherimide (PEI) and so on. Among them, polyethylene terephthalate (PET), polyethylene naphthalate (PEN) and so on are preferable as the transparent substrate 2.

The transparent electrode (cathode) 3 is provided in a thin-film shape on the upper surface of the transparent substrate 2. As a transparent electrode substance constituting the transparent electrode (cathode) 3, a transparent oxide such as indium tin oxide (ITO), an organic transparent electrode such as conductive polymer, graphene thin film, graphene oxide thin film, carbon nanotube thin film, and an organic/inorganic coupled transparent electrode such as a carbon nanotube thin film coupled with metal can be used. Among them, the indium tin oxide (ITO), and graphene thin film and so on are preferable as the transparent electrode substance.

The hole transport layer 4 is for collecting the holes generated in the electron donor layer 5 and transporting them to the transparent electrode (cathode) 3, and is provided in a thin-film shape between the transparent electrode 3 and the electron donor layer 5. As a hole transport substance constituting the hole transport layer 4, for example, poly (3,4-ethylenedioxythiophene)-polystyrene sulfonate (PEDOT:PSS), polyaniline, copper phthalocyanine (CuPC), polythiophenylenevinylene, polyvinycarbazole, polyparaphenylenevinylene, polymethylphenylsilane and so on can be used. Among them, PEDOT:PSS is preferable. Note that one kind of them may be used or two or more kinds of them may be used in combination.

The electron transport layer 8 is for collecting the electrons accumulated in the electron acceptor layer 6 and transporting them to the metal electrode 9 and is formed in a thin-film shape between the electron acceptor layer 6 and the metal electrode 9. As an electron transport substance constituting the electron transport layer 8, for example, lithium fluoride (LF), calcium, lithium, titanium oxide and so on can be used. Among them, LiF, titanium oxide and so on can be preferably used.

As a metal electrode substance constituting the metal electrode (anode) 9, calcium, lithium, aluminum, an alloy of lithium fluoride and lithium, gold, conductive polymer or a mixture thereof can be used. Among them, aluminum, gold and so on can be preferably used.

According to the present embodiment, an organic thin-film solar cell in which both the charge separation efficiency and the charge transport efficiency can be improved to stably achieve excellent photoelectric conversion efficiency can be produced by making a photoelectric conversion layer such that at least one of an electron donor substance constituting an electron donor layer and an electron acceptor substance constituting an electron acceptor layer is made of a liquid crystalline organic material and the electron donor layer and the electron acceptor layer are regularly phase-separated.

The organic thin-film solar cell 1 of the present embodiment can be produced as follows for instance.

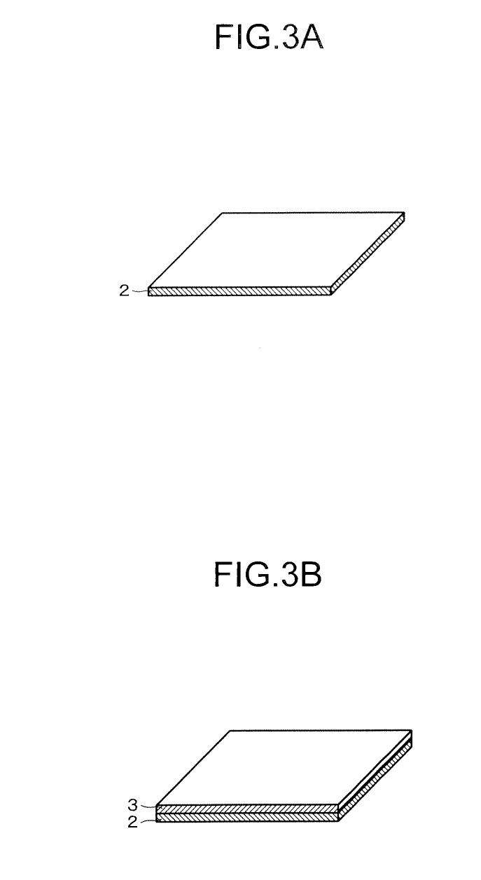

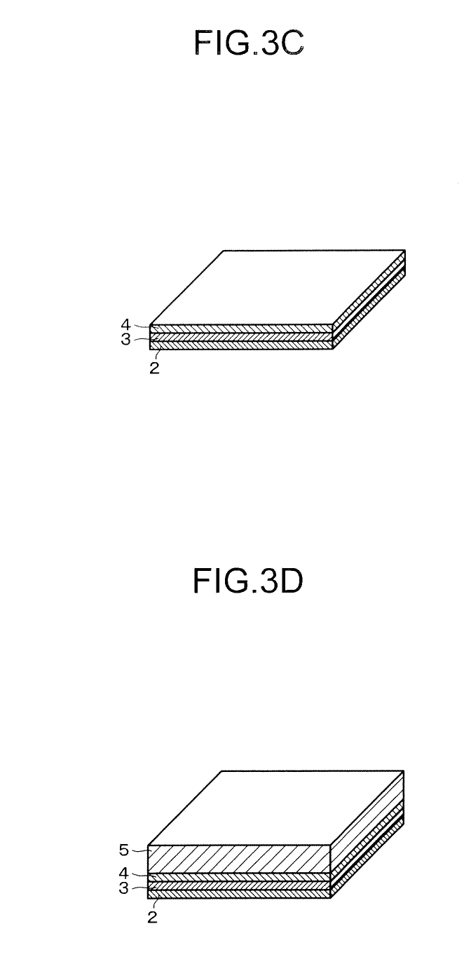

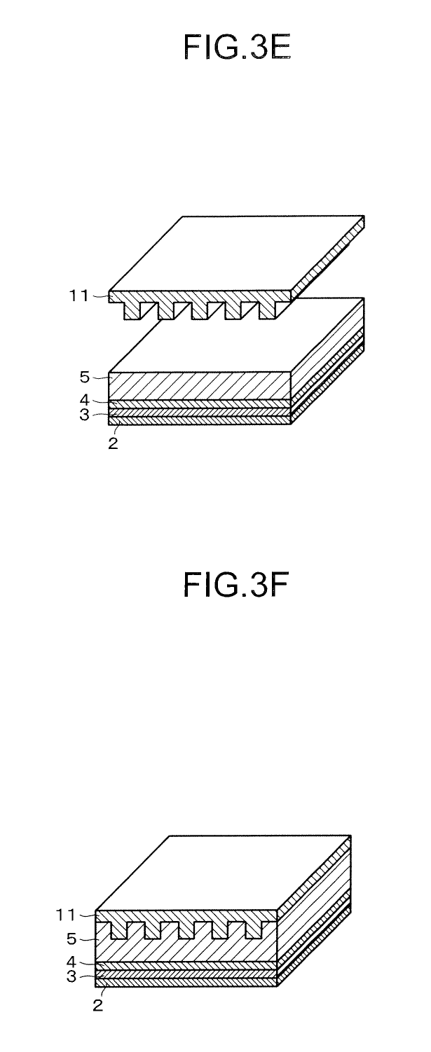

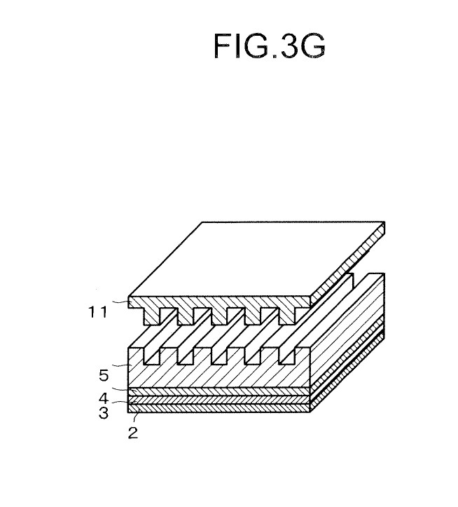

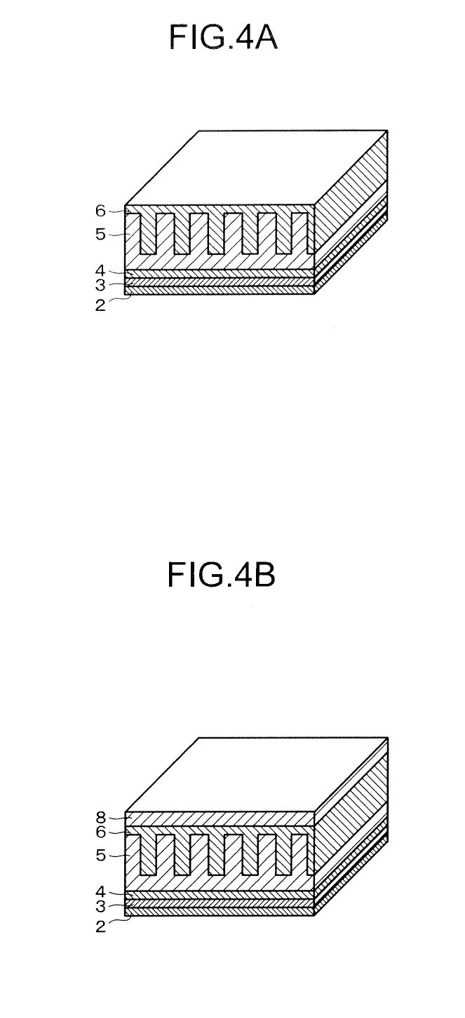

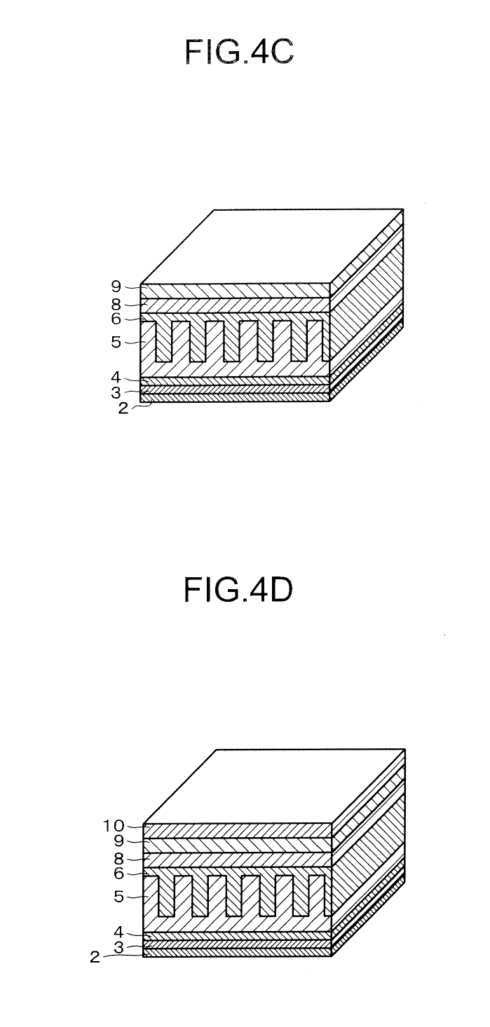

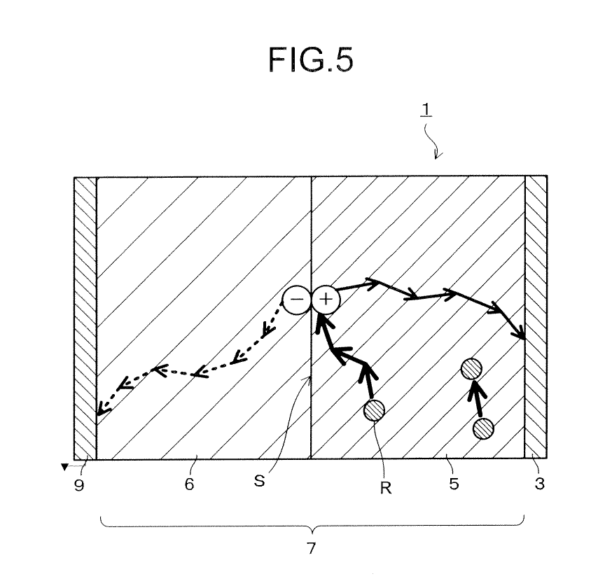

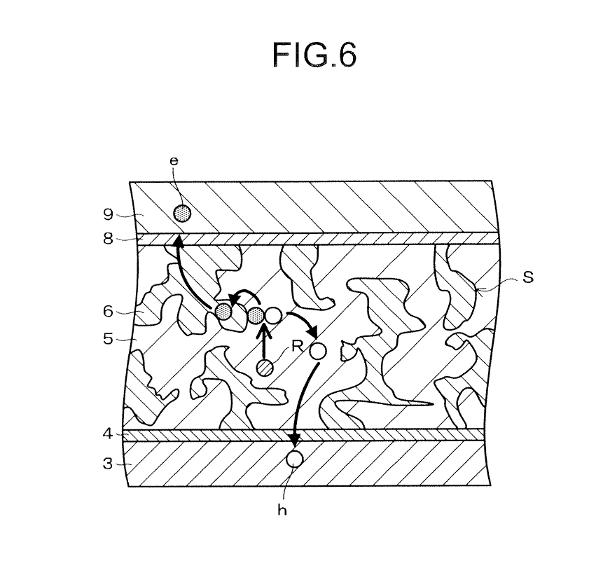

FIG. 3A to 3G and FIG. 4A to 4D are perspective views illustrating an example of production process of the organic thin-film solar cell of the embodiment. First of all, prepare the transparent substrate 2 (FIG. 3A), and on the transparent substrate 2, the transparent electrode (cathode) 3 is formed (FIG. 3B). As the transparent substrate 2, a glass substrate or a polymer substrate can be used. In the case of the glass substrate, it is preferable to use a glass substrate having a uniform thickness of 0.3 to 1.0mm. When the thickness of the glass substrate is less than 0.3 mm, its handling may be difficult. On the other hand, when the thickness of the glass substrate exceeds 1.0 mm, the light transmission property may be insufficient or the substrate may be too heavy. In the case of the polymer substrate, it is preferable to use a polymer substrate having a uniform thickness of 50 to 300 μm. When the thickness of the polymer substrate is less than 50 μm, the amounts of oxygen and moisture passing through the substrate increase and may damage the photoelectric conversion layer 7. On the other hand, when the thickness of the polymer substrate exceeds 300 μm, the light transmission property may be insufficient.

The transparent electrode 3 can be formed by sputtering or coating the above-described transparent electrode substance. In the case of forming by coating, the transparent electrode 3 can be formed by coating a solution, which is obtained by dissolving the transparent electrode substance in a solvent such as water or methanol, onto the transparent substrate 2 by a spin coating method or the like and drying the solution. The drying can be performed, for example, by keeping the substrate at a temperature of 100 to 200° C. for 1 to 60 minutes.

The thickness of the transparent electrode 3 is not particularly limited but is preferably 1 to 200 nm and more preferably 100 to 150 nm.

The sheet resistance of the transparent substrate 2 on which the transparent electrode 3 is formed is preferably 5 to 100 Ω/sq. and more preferably 5 to 20 Ω/sq. When the sheet resistance is less than 5 Ω2/sq., the transparent electrode 3 may be colored to decrease the light absorption amount of the photoelectric conversion layer 7. On the other hand, when the sheet resistance exceeds 100 Ω/sq., the sheet resistance is too high and may fail to achieve the power generation effect.

Subsequently, a film of the hole transport substance is formed on the upper surface of the transparent electrode 3 to form the hole transport layer 4 (FIG. 3C). The method of forming the hole transport layer 4 can be implemented, for example, such that the above-described hole transport substance is coated by a spin coating method and dried. The drying can be performed, for example, by keeping the substrate at a temperature of 120 to 250° C. for 5 to 60 minutes.

The thickness of the hole transport layer 4 is preferably 30 to 100 nm and more preferably 30 to 50 nm. When the thickness of the hole transport layer 4 is less than 30 nm, the electron blocking effect and a function as a buffer layer may not be sufficiently attained. On the other hand, when the thickness of the hole transport layer 4 exceeds 100 nm, the sheet resistance may be too high due to the electric resistance of the hole transport layer 4 itself, or the light absorption amount in the photoelectric conversion layer 7 may decrease due to light absorption by the hole transport layer 4 itself.

On the upper surface of the hole transport layer 4, a film of the electron donor substance is formed to form the electron donor layer 5 (FIG. 3D). The method of forming the electron donor layer 5 can be implemented, for example, such that a solution obtained by dissolving the above-described electron donor substance in an organic solvent such as toluene, chloroform, chlorobenzene or the like is filtrated by a filter or the like, coated onto the upper surface of the hole transport layer 4 by printing, a spin coating method or the like and dried. The drying does not always need to be performed. The drying, when performed, may be performed, for example, by keeping the substrate at a temperature of 120 to 250° C. for 1 to 60 minutes.

Thereafter, a pattern is formed on the surface of the above-described electron donor layer 5 using a nano-imprint method (FIG. 3E to 3G). In the nano-imprint method, for example, when the liquid crystalline organic material is used for the electron donor layer 5, a mold 11 having a fine pattern structure is placed on the electron donor layer 5 (FIG. 3E), and the mold 11 is pressed at a predetermined pressure at a temperature equal to or higher than the glass transition temperature of the liquid crystalline organic material (FIG. 3F) to transfer the pattern of the mold to the electron donor substance by plastic deformation to thereby form a reverse phase structure of the mold on the surface of the electron donor layer 5 (FIG. 3G).

The pressing force of the mold 11 to the electron donor substance is preferably 100 to 100,000 N, more preferably 500 to 50,000 N, and particularly preferably 500 to 5000 N. When the pressing force is less than 100 N, the pattern shape may not sufficiently be formed on the electron donor layer 5. On the other hand, when the pressing force exceeds 100,000 N, the mold 11 may be broken or the transparent substrate 2 may be broken. The temperature when forming the pattern on the surface of the electron donor layer 5 by pressing the mold 11 thereon is preferably equal to or higher than the glass transition temperature and equal to or lower than the glass transition temperature+60° C., and more preferably equal to or higher than the glass transition temperature+20° C. and equal to or lower than the glass transition temperature+40° C.

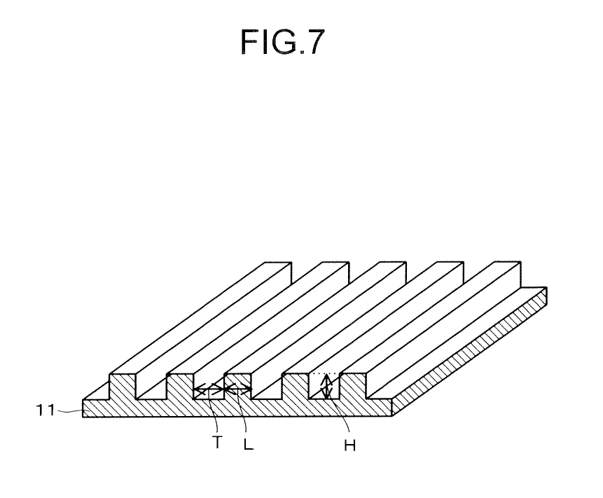

As the mold 11, a mold made of a material such as, for example, metal, metal oxide, ceramic, semiconductor, or thermosetting polymer can be used, but the mold is not particularly limited as long as it can form a fixed pattern on a layer applied with the electron donor substance or the electron acceptor substance. Further, examples of the shape of projecting portions of the mold 11 include, for example, cone, column, regular hexahedron, rectangular parallelepiped, semicircle, hollow column, hollow hexahedron, nano-line array and so on. Among them, the rectangular parallelepiped mold can stably form a pattern on a molded body and is thus preferably used. It is preferable that the each projecting portions of the mold 11 are formed at a fixed height in a direction in which they are extended and the heights of the projecting portions are the same. It is also preferable that the width (L) of the projecting portion and the width (T) of the recessed portion of the mold 11 are almost the same. For example, the mold 11 in the shape illustrated in FIG. 7 is preferable.

The mold 11 can be produced by various methods conventionally used in this kind of usage, such as a method of producing a fine pattern on a silicon wafer by a lithography process, a method of producing a fine pattern by oxidizing metal such as aluminum, a method of producing a fine pattern by using an electron beam lithography process, a method by a soft lithography process such as the nano-imprint or photolithography process, or a method of using a replica obtained by replicating the mold produced by the above-described methods.

The mold 11 preferably has a pattern structure with a pattern cycle of 5 to 1000 nm, preferably 5 to 200 nm and more preferably 10 to 100 nm. When the pattern cycle of the mold 11 exceeds 1000 nm, the width of the teeth 5a of the electron donor layer 5 and the teeth 6a of the electron acceptor layer 6 become too large as compared to the exciton diffusion distance, so that sufficient charge separation efficiency may not be achieved in the produced photoelectric conversion layer 7. On the other hand, when the pattern cycle of the mold 11 is less than 5 nm, the width of the teeth 5a of the electron donor layer 5 and the teeth 6a of the electron acceptor layer 6 become too small, the electron and the hole separated at the joint surface S between the electron donor layer 5 and the electron acceptor layer 6 become likely to recombine at another joint surface S and may actually decrease the charge separation efficiency. For example, in the case of using the mold illustrated in FIG. 7, a width (L) of the projecting portion is preferably 5 to 1000 nm and more preferably 10 to 50 nm, a width (T) of the recessed portion is preferably 5 to 1000 nm and more preferably 10 to 50 nm, and a height (H) of the projecting portion is preferably 50 to 1000 nm and more preferably 100 to 500 nm.

Further, on the upper surface of the patterned electron donor layer 5, a film of the electron acceptor substance is formed to form the electron acceptor layer 6 and thereby form the photoelectric conversion layer 7 (FIG. 4A). The method of forming the electron acceptor layer 6 can be implemented, for example, such that the electron acceptor substance is deposited on top of the patterned electron donor layer 5 by a method such as a vacuum deposition method, a sputtering method or the like or a solution obtained by dissolving the electron acceptor substance in a solvent is coated onto the patterned electron donor layer 5 by a method such as a spin coating method, a doctor blade method or the like and dried. Here, the deposition of the electron acceptor substance and the coating of the electron acceptor substance dissolved in the solvent can also be performed using a shadow mask. Among them, the vapor deposition method is preferably used in terms of forming a film of the electron acceptor substance in a uniform thickness on the upper surface of the electron donor layer 5 and in consideration of the case where the electron donor substance is likely to dissolve in the solvent used for coating forming the electron acceptor layer 6. When forming the electron acceptor layer 6 by coating, the drying may be performed, for example, by keeping the substrate at a temperature of 120 to 250° C. for 1 to 60 minutes.

When the electron donor substance constituting the electron donor layer 5 is a liquid crystalline organic material, thermal treatment is performed at a temperature at which the liquid crystalline organic material exhibits liquid crystallinity. Concretely, after the electron donor layer 5 is formed or after the electron acceptor layer 6 is formed, the thermal treatment is performed, for example, at 50 to 200° C. This makes it possible to orient the liquid crystalline molecules in the electron donor layer 5 in a fixed direction. When the electron acceptor substance constituting the electron acceptor layer 6 is a liquid crystalline organic material, thermal treatment is performed, for example, at 50 to 200° C. after the electron acceptor layer 6 is formed.

Further, on the upper surface of the electron acceptor layer 6, a film of the electron transport substance can be formed to form the electron transport layer 8 (FIG. 4B). The method of forming the electron transport layer 8 can be implemented, for example, such that the electron transport substance is deposited on the upper surface of the electron acceptor layer 6 by a method such as a vacuum deposition method, a sputtering method or the like or a solution obtained by dissolving the electron transport substance in a solvent is coated on the upper surface of the electron acceptor layer 6 by a method such as a spin coating method, a doctor blade method or the like and dried. Among them, the vapor deposition method is preferably used in terms of uniformly forming a film of the electron transport substance on the surface of the electron donor layer. Note that the deposition of the electron transport substance and the coating of the electron transport substance dissolved in the solvent can also be performed using a shadow mask.

The electron transport layer 8 does not always need to be provided. The electron transport layer 8, when provided, preferably has a thickness of 0.1 to 5 nm and more preferably 0.1 to 1 nm. When the thickness of the electron transport layer 8 is less than 0.1 nm, the control of the film thickness may become difficult to fail to achieve stable characteristics. On the other hand, when the thickness of the electron transport layer 8 exceeds 5 nm, the sheet resistance may become too high to decrease the current value.

The metal electrode (anode) 9 is formed on top of the electron transport layer 8 when the electron transport layer 8 is formed, or on top of the electron acceptor layer 6 when the electron transport layer 8 is not formed (FIG. 4C). The method of forming the metal electrode 9 can be implemented such that the metal electrode substance is deposited on the upper surface of the electron transport layer 8 by a method, for example, a vapor deposition method or the like. Note that the deposition of the metal electrode substance can also be performed using a shadow mask.

The thickness of the metal electrode 9 is preferably 50 to 300 nm and more preferably 50 to 100 nm. When the thickness of the metal electrode 9 is less than 50 nm, the photoelectric conversion layer 7 may be damaged by moisture, oxygen and the like, and the sheet resistance may become too high. On the other hand, when the thickness of the metal electrode 9 exceeds 300 nm, time required for formation of the metal electrode 9 becomes too long, and the cost may increase.

Subsequently, the substrate 10 is formed on the upper surface of the metal electrode 9 (FIG. 4D). The substrate 10 can be placed on the upper surface of the metal electrode 9 by being bonded using, for example, epoxy resin, acrylic resin or the like. As the substrate 10, a substrate having the same size and same material as those of the transparent substrate 2 is preferably used, but is not always transparent like the transparent substrate 2.

The method for producing the organic thin-film solar cell of the present embodiment has been described above but is not always limited to the above method. The order of forming the respective parts and so on can be arbitrarily changed as long as the organic thin-film solar cell 1 can be produced.

### EXAMPLES

Hereinafter, the embodiments will be described in more detail using examples but will not be interpreted as limited to them.

### Example 1

A glass substrate (a plate thickness: 0.7 mm, a sheet resistance of ITO: 10 Ω/sq.) with ITO having a film thickness of 140 nm was washed with alkali detergent, ultrapure water, acetone, and i-propanol in order for 10 minutes each using an ultrasonic washing machine, and then cleaned with ultraviolet ozone for 3 minutes.

On the transparent electrode, a poly (3,4-ethylenedioxythiophene)-polystyrene sulfonate solution (manufactured by H.C. Starck: trade name “Baytoron P”) after filtrated using a filter of 0.45 μm was coated by a spin coating method and dried in the atmosphere at 140° C. for 10 minutes to form the hole transport layer. The film thickness of the hole transport layer was 50 nm.

Poly[(9,9-dioctylfluorenyl-2,7-diyl)-co-bithiophene] (manufactured by Aldrich) that is the electron donor substance was dissolved in chlorobenzene and thereby adjusted to 7 mg/ml to prepare a solution. This solution was filtrated using a filter of 0.20 μm and then coated onto the hole transport layer by spin coating. Then, the substrate was kept at 290° C. for 60 minutes to orient the liquid crystalline molecules contained in the electron donor layer in a fixed direction.

A pattern was formed on the surface of the electron donor layer formed on the transparent substrate by a nano-imprint method using a silicone mold (manufactured by Kyodo International, projecting portion width (L)/recessed portion width (T)/projecting portion height (H)=500 nm/500 nm/200 nm) illustrated in FIG. 7. The temperature at the nano-imprint was set to 150° C. and the pressure was set to 1000 N.

The transparent substrate with the electron donor layer having the pattern formed on the surface was placed in a vacuum deposition apparatus, and a shadow mask was placed on the electron donor layer. Thereafter, the pressure inside the vacuum deposition apparatus was reduced down to 10⁻³ Pa and fullerene (C₆₀) as the electron acceptor substance was deposited (film thickness of 240 nm) on the upper surface of the electron donor layer.

Subsequently, the shadow mask placed on the electron donor layer was replaced with another shadow mask, and the pressure inside the vacuum deposition apparatus was then reduced down to 10⁻³ Pa again and thereby aluminum was deposited on the surface of the electron acceptor layer to form the metal electrode. The thickness of the metal electrode was 100 nm. On the metal electrode, the glass substrate was bonded using an epoxy resin (UVRESIN XNR5570 manufactured by Nagase ChemteX) to produce an organic thin-film solar cell.

An organic thin-film solar cell of the present embodiment is excellent in charge separation efficiency and charge transport efficiency and high in photoelectric conversion efficiency, and is useful in industry. Incidentally, all contents of the specification, claims, drawings, and abstract of Japanese Patent Application No. 2010-150500, filed on Jun. 30, 2010 are cited in their entirety herein and are incorporated as a disclosure of the specification of the present invention.

What is claimed is:

1. An organic thin-film solar cell, comprising in series:
a transparent substrate;
a cathode;
a photoelectric conversion layer having a regular phase-separated structure composed of an electron donor layer and an electron acceptor layer, at least one of the electron acceptor layer and the electron donor layer having a liquid crystalline organic material containing oriented liquid crystalline molecules;
an anode; and
a substrate.

2. The organic thin-film solar cell according to claim 1,
Wherein each of the electron acceptor layer and the electron donor layer has cross-section of a comb-teeth shape with a plurality of teeth facing the cathode or the anode, and the teeth fit with each other to form the phase-separated structure.

3. The organic thin-film solar cell according to claim 1,
wherein at least one of the electron acceptor layer and the electron donor layer is formed by using a nano-imprint method.

4. The organic thin-film solar cell according to claims 1,
wherein the electron acceptor layer and the electron donor layer are separately and alternately formed between the cathode and the anode in a direction perpendicular thereto.

5. The organic thin-film solar cell according to claims 2,
wherein each of the teeth has width from 5 to 1000 nm.

6. The organic thin-film solar cell according to claims 1,
wherein the electron donor layer has a thickness from a surface thereof closest to a main surface of the cathode to a surface thereof closest to a main surface of the anode ranging from 50 to 1000 nm and the electron acceptor layer has a thickness from a surface thereof closest to the main surface of the anode to a surface thereof closest to the main surface of the cathode ranging from 50 to 1000 nm.

7. The organic thin-film solar cell according to claims 1,
wherein a hole transport layer is provided between the cathode and the electron donor layer, and an electron transport layer is provided between the anode and the electron acceptor layer.

8. The organic thin-film solar cell according to claims 1,
wherein an electron donor substance constituting the electron donor layer contains one or more kinds of liquid crystalline organic materials selected from a group consisting of a compound with only a 6-membered ring as an aromatic ring, a compound with only a 5-membered ring as an aromatic ring, and a compound with a combination of a 5-membered ring and a 6-membered ring as aromatic rings.

9. A method for producing an organic thin-film solar cell, comprising:
a step (a) of forming a cathode electrode on a transparent substrate;
a step (b) of forming a hole transport layer by forming a film of a hole transport substance on top of the cathode electrode;
a step (c) of forming an electron donor layer by forming a film of an electron donor substance on top of the hole transport layer;
a step (d) of forming a pattern on top of the electron donor layer by a nano-imprint method;
a step (e) of forming an electron acceptor layer by forming a film of an electron acceptor substance on top of the electron donor layer having the pattern formed thereon to thereby form a photoelectric conversion layer;
a step (f) of forming an electron transport layer by forming a film of an electron transport substance on top of the photoelectric conversion layer;
a step (g) of forming an anode electrode on top of the electron transport layer; and
a step (h) of forming a substrate on top of the anode electrode, at least one of the electron donor substance and the electron acceptor substance being a liquid crystalline organic material containing liquid crystalline molecules.

10. The method for producing an organic thin-film solar cell according to claim 9,
wherein thermal treatment is performed between the step (d) and the step (e) or between the step (e) and the step (f) at a temperature at which the liquid crystalline material exhibits liquid crystallinity to form an orientation state of the liquid crystalline molecules.
